(19) United States
(12) Patent Application Publication
(10) Pub. No.: US 2026/0109898 A1
(43) Pub. Date: Apr. 23, 2026

(54) USE OF A COMPOSITION AND A PROCESS FOR SELECTIVELY ETCHING SILICON

(71) Applicant: BASF SE, Ludwigshafen Am Rhein (DE)

(72) Inventors: Francisco Javier LOPEZ VILLANUEVA, Ludwigshafen am Rhein (DE); Sven HILDEBRANDT, Muelheim an der Ruhr (DE); Andreas KLIPP, Ludwigshafen am Rhein (DE); Rohini GUPTA, Fremont, CA (US)

(21) Appl. No.: 19/112,784

(22) PCT Filed: Oct. 2, 2023
(86) PCT No.: PCT/US2023/034298

§ 371 Date: Mar. 18, 2025

(30) Foreign Application Priority Data
Oct. 6, 2022 (EP) 22200148.9

(51) Int. Cl. C09K 13/00; H10P 50/64

(52) U.S. Cl. CPC C09K 13/00; H10P 50/646

(57) ABSTRACT

Described herein is a method of using a composition for selectively etching a silicon layer in the presence of an n-doped silicon layer at a temperature from 10 to 50° C., the composition including:
(a) 0.1 to 15% by weight of a selectivity enhancer selected from the group consisting of a C₁ to C₂₀ primary alkylamine, a C₁ to C₂₀ secondary alkylamine, a C₁ to C₂₀ primary alkanolamine, and a C₁ to C₂₀ secondary alkanolamine; and
(b) water;
where the n-doped silicon has a content of from 10¹⁶ cm⁻³ to 10²² cm⁻³ of a group 13 or 15 element.

The present application claims priority to European Patent Application No. 22200148.9, filed Oct. 6, 2022, the disclosure of which is hereby incorporated by reference in its entirety as if fully set forth herein.

The present invention relates to the use of a composition and a process for selectively etching silicon at a surface of a microelectronic device substrate, relative to etching n-doped silicon containing material.

### BACKGROUND OF THE INVENTION

Steps of preparing certain microelectronic devices, e.g., integrated circuits, may include selectively removing silicon (Si) material from a surface that contains the Si in combination with phosphorous doped silicon (Si:P). Introduction of boron or phosphorous has an important implication for the electronic features of the Si structures but does not affect alkaline etching until a concentration of 10¹⁸-10¹⁹ atoms/cm³. Beyond that point, etch rates decline for both types of dopants. Interestingly, p-type doping (introduction of boron, Si:B) leads to increased alkaline etching of Si(111) over n-type (introduction of phosphorous, Si:P) doping of Si(111) (B. Gokce et al. J. Vac. Sci. Technol. A 30, 040603 (2012); DOI: 10.1116/1.4721329).

The etch rate reduction for increasing concentrations of phosphorous is less pronounced than for boron (H. Seidel et al. J. Electrochem. Soc. 137 (1990), 3626). Some experiments showed that under standard alkaline conditions with TMAH at 55° C. or 30° C. selectivities below 5 for poly-Si over poly-Si:P can be reached. Etch rates of poly-Si and poly-Si:P (P-concentration 7·10¹⁹ at/cm³) were similar under these conditions. This is in accordance with the literature, where it was reported that only beyond a P-concentration of 10¹⁹ at/cm³, the poly-Si:P etch rate decreases with alkaline etchants. TMAH therefore does not allow selective removal of poly-Si over phosphorous doped poly-Si. Selectivity of at least 10:1 would be needed, preferably 20:1.

US 2022/298417 A1 discloses an etching solution suitable for the selective removal of polysilicon over p-doped silicon from a microelectronic device, comprising water; at least one of NH₄OH or a quaternary ammonium hydroxide; at least one compound selected from benzoquinone; quinoline (or derivatives thereof); an unsubstituted or substituted C₈₋₂₀ aliphatic acid; a C₄₋₁₂ alkylamine; and a polyalkylenimine; optionally at least one water-miscible organic solvent; and optionally, at least one compound selected from an alkanolamine and a polyamine, and mixtures thereof.

The state-of-the-art solutions are not able to fulfil all requirements since they have at least one of the following deficiencies:
(a) a too low Si/Si:P selectivity, to remove the Si layer(s) without attacking the n-doped silicon layer;
(b) a too low Si etch rate which leads to a long time to completely remove the silicon layer(s); or
(c) a too high n-doped silicon, particularly Si:P, etch rate which leads to a removal of the n-doped silicon layer(s) on top of the silicon layer(s).

It is therefore an object of the invention to increase the silicon vs n-doped silicon, particularly Si vs Si/Si:P selectivity without reducing the etch rate with respect to Si too much.

### SUMMARY OF THE INVENTION

It has now been found that the use of primary or secondary amines or alkanolamines significantly and selectively improve the silicon/doped silicon selectivity since the etching rate of silicon layers, particularly crystalline, poly-crystalline or amorphous silicon layers is much more reduced than the etching of the n-doped silicon layer.

Therefore, one embodiment of the present invention is the use of a composition for selectively etching a silicon layer in the presence of an n-doped silicon layer at a temperature from 10 to 50° C., the composition comprising:
(a) 0.1 to 15% by weight of a selectivity enhancer selected from a C₁ to C₂₀ primary alkylamine, a C₁ to C₂₀ secondary alkylamine, a C₁ to C₂₀ primary alkanolamine, and a C₁ to C₂₀ secondary alkanolamine;
(b) water;
wherein the n-doped silicon has a content of from 10¹⁶ cm⁻³ to 10²² cm⁻³, preferably of from 10¹⁷ cm⁻³ to 10²¹ cm⁻³, most preferably of from 10¹⁸ cm⁻³ to 10²⁰ cm⁻³ of a group 13 or 15 element.

It was particularly surprising that the etching composition according to the invention is suited to allow for a very controlled and selective etching of layers comprising or consisting of elemental silicon (Si), preferably of amorphous silicon (aSi) or crystalline silicon, while at the same time not or not significantly compromising layers comprising or consisting of a silicon that is doped with a group 15 element, particularly phoshorous (Si:P).

Another embodiment of the present invention is a process of selectively removing silicon layer from a surface of a microelectronic device relative to an n-doped silicon layer, the process comprising:
(a) providing a microelectronic device surface that includes the silicon layer and the n-doped silicon layer, wherein the n-doped silicon layer has a content of 10¹⁶ cm⁻³ to 10²² cm⁻³ of a group 13 or 15 element;
(b) providing an etching composition comprising
   (i) 0.1 to 15% by weight of a selectivity enhancer selected from a C₁ to C₂₀ primary alkylamine, a C₁ to C₂₀ secondary alkylamine, a C₁ to C₂₀ primary alkanolamine, and a C₁ to C₂₀ secondary alkanolamine; and
   (ii) water;
(c) contacting the surface with the composition at a temperature of 10 to 50° C. for a time and at a temperature effective to selectively remove the silicon layer relative to the n-doped silicon layer.

### DETAILED DESCRIPTION OF THE INVENTION

The purpose of the etching composition is the etching of silicon (Si) layers in the presence of n-doped silicon layers.

The composition used in the subject invention comprises 0.1 to 15% by weight of a C₁ to C₂₀ primary or secondary alkylamine or a C₁ to C₂₀ primary or secondary alkanolamine; and water. It is used for selectively etching a silicon layer in the presence of an n-doped silicon layer having a content of from 10¹⁶ cm⁻³ to 10²² cm⁻³, preferably of from 10¹⁷ cm⁻³ to 10²¹ cm⁻³, most preferably of from 10¹⁸ cm⁻³ to 10²⁰ cm⁻³ of a group 13 or 15 element in a temperature range of from 10 to 50° C.

### Definitions

As used herein, a “primary amine” is an amine comprising at least one primary amine functional group. As used herein, a “secondary amine” is an amine comprising at least one secondary but no primary amine functional group. As used herein, a “tertiary amine” is an amine comprising at least one tertiary but no secondary or primary amine functional group.

As used herein, a “silicon layer” or “Si layer” is a layer that essentially consists of elemental silicon, preferably consists of elemental silicon. It particularly includes includes, but is not limited to, a layer consisting of amorphous, poly-crystalline or (single-) crystalline silicon. The etching composition is particularly useful when etching silicon, in particular amorphous silicon (aSi) in the presence of Si:P or Si:As. The term “essentially consisting of silicon” means that the silicon content in the layer is more than 90% by weight, preferably more than 95% by weight, even more preferably more than 98% by weight. It is particularly preferred that the silicon layer dos not comprises any other elements than silicon. Preferably, the doping element content of the silicon layer is less than 0.1% by weight, preferably less than 0.01% by weight, more preferably less than 0.001% by weight. Most preferably the silicon layer comprises no other elements than silicon.

As used herein, “doped silicon” layers correspond to layers comprising or consisting of silicon doped with group 15 elements known in the art. The n-doped silicon layer usually has a content of 10¹⁶ cm⁻³ to 10²² cm⁻³, most preferably 10¹⁸ cm⁻³ to 10²⁰ cm⁻³ of a group 13 or 15 element. Typical doping elements, without being restricted thereto, are phosphorous (Si:P) and arsenic (Si:As). n-doping with phosphorous (Si:P) is particularly preferred.

As used herein, “selectively etching” (or “selective etch rate”) preferably means that upon applying a composition according to the invention to a layer comprising or consisting of a first material, in this case Si, most particularly aSi, in the presence of a layer comprising or consisting of a second material, in this case n-doped silicon, particularly Si:P, the etch rate of said composition for etching the first layer is at least 30 times, preferably at least 50 times, even more preferably at least 100 times, most preferably at least 150 times the etch rate of said composition for the second layer. Depending on the substrate to be etched, other layers like SiOₓ, SiON or SiN should also not be jeopardized.

As used herein, “layer” means a part of a substrate that was separately disposed on the surface of a substrate and has a distinguishable composition with respect to adjacent layers.

As used herein, “chemical bond” means that the respective moiety is not present but that the adjacent moieties are bridged so as to form a direct chemical bond between these adjacent moieties. By way of example, if in a molecule A-B-C the moiety B is a chemical bond then the adjacent moieties A and C together form a group A-C.

The term “Cₓ” means that the respective group comprises x numbers of C atoms. The term “Cₓ to C_{y} alkyl” means alkyl with a number x to y of carbon atoms and, unless explicitly specified, includes unsubstituted linear, branched and cyclic alkyl. As used herein, “alkanediyl” refers to a diradical of linear, branched or cyclic alkanes or a combination thereof.

All percent, ppm or comparable values refer to the weight with respect to the total weight of the respective composition except where otherwise indicated. The terms “wt %” and “% by weight” are used herein synonymously.

All cited documents are incorporated herein by reference.

### Si Selectivity Enhancer

It has been found that 0.1 to 15% by weight of a a selectivity enhancer selected from a C₁ to C₂₀ primary or secondary alkylamine and a C₁ to C₂₀ primary or secondary alkanolamine selectively etches silicon layers, preferably aSi, whereas the etch rate of layers comprising or consisting of n-doped silicon, preferably phosporous doped silicon, are suppressed, which leads to a-Si/Si:X (X=P, As) selectivities above 10 or even above 20.

In a preferred embodiment the composition comprises a C₁ to C₁₀ primary amine or a C₁ to C₁₀ primary alkanolamine.

In another preferred embodiment, an alkylamine of formula E1

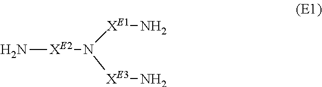

is used, wherein X^{E1}, X^{E1}, and X^{E1} are independently selected from a C₂-C₆ alkanediyl.

Preferably X^{E1}, X^{E2}, and X^{E3} may be selected from ethane-1,1-diyl, and ethane-1,2-diyl. In another preferred embodiment X^{E1} X^{E1}, X^{E1} may be selected from propane-1,1-diyl, butane-1,1-diyl, pentane-1,1-diyl, and hexane-1,1-diyl. In yet another preferred embodiment XS may be selected from propane-2-2-diyl, butane-2,2-diyl, pentane-2,2-diyl, and hexane-2,2-diyl. In yet another preferred embodiment X^{E1}, X^{E2}, and X^{E3} may be selected from ethane-1-2-diyl, butane-1,2-diyl, pentane-1,2-diyl, and hexane-1,2-diyl. In yet another preferred embodiment XS may be selected from propane-1-3-diyl, butane-1,3-diyl, pentane-1,3-diyl, and hexane-1,3-diyl. Particular preferred groups X^{E1}, X^{E2}, and X^{E3} are ethane-1,2-diyl, propane-1,3-diyl, propane-1,2-diyl, or a divalent N,N-piperazine (1,4-Diazacyclohexane) group.

In yet another preferred embodiment, an alkanolamine is a compound of formula E2a or E2b

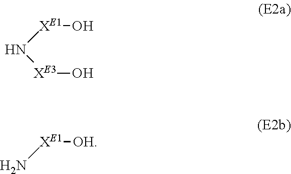

are used, wherein X^{E1}, X^{E1}, X^{E1} are independently selected from a C₂-C₆ alkanediyl. Preferably X^{E1}, X^{E2}, and X^{E3} may have the meanings described with respect to formula E1 above.

Particularly preferred selectivity enhancers are ethanolamine, propanolamine, tris-(2-aminoethyl)amine (TREN), tris-(3-aminopropyl)amine, and 1-(2-Aminoethyl)piperazine.

The selectivity enhancer may be present in an amount of from about 0.1 to about 15% by weight. If the amount is too low, the enhancing effect is too low. A further increase of the concentration is technically possible but does not make sense for commercial reasons. Preferred concentrations are from about 2 to about 12% by weight, even more preferred from about 3 to about 10% by weight. The optimal concentration window is of from 4 to 7% by weight.

The composition according to the invention may comprise one or more of the selectivity enhancers described herein.

### Water

The etching compositions of the present development are aqueous-based and, thus, comprise water. Water has several functions such as, for example, to dissolve one or more components of the composition, as a carrier of the components, as an aid in the removal of residue, as a viscosity modifier of the composition, and as a diluent. Preferably, the water employed in the composition is de-ionized (DI) water. The ranges of water described in the next paragraph include all of the water in the composition from any source.

For most applications, the weight percent of water in the composition will be present in a range with start and end points selected from the following group of numbers: 35, 40, 45, 50, 55, 60, 65, 70, 75, 80, 85, 90, 92, 94, 96. Examples of the ranges of water that may be used in the composition include, for examples, from about 45 to about 96% by weight, or about 50 to about 94% by weight of water; or from about 60 to about 96% by weight, or from about 70 to about 96% by weight, or from about 80 to about 96% by weight, or from about 85 to about 96% by weight, or from about 90 to about 96% by weight. Still other preferred embodiments of the present invention may include water in an amount to achieve the desired weight percent of the other ingredients.

### Organic Solvents

The etching composition may optionally comprise one or more water-miscible organic solvents.

Examples of water-miscible organic solvents that can be employed are ethylene glycol, propylene glycol, 1,4-butanediol, glycerol, tripropylene glycol methyl ether, propylene glycol propyl ether, diethylene gycol n-butyl ether (BDG), dipropylene glycol methyl ether (DPM) hexyloxypropylamine, poly(oxyethylene)diamine, dimethylsulfoxide (DMSO), tetrahydrofurfuryl alcohol, glycerol, alcohols, sulfolane, sulfoxides, ethanolamine, diethanolamine, triethanolamine or mixtures thereof. Preferred solvents are alcohols, diols, or mixtures thereof. Most preferred solvents are C₂ to C₆ polyols, particularly C₂ to C₄ polyols, including diols, such as, for example, ethylene glycol or propylene glycol, and triols, such as, for example, glycerol.

For most applications, the amount of water-miscible organic solvent in the composition may be in a range having start and end points selected from the following list of weight percents: 0.5, 1, 5, 7, 10, 12, 15, 20, 25, 29, 30, 33, 35, 40, 44, 49.5, 50. Examples of such ranges of solvent include from about 0.5 to about 50% by weight; or from about 1 to about 45% by weight; or from about 1 to about 40% by weight; or from about 0.5% to about 30% by weight; or from about 1 to about 30% by weight; or from about 5 to about 30% by weight; or from about 5 to about 20% by weight; or from about 7 to about 20%, or from about 10 to about 30% by weight; or from about 15 to about 25% by weight of the composition.

In individual cases, a composition according to the invention as defined herein may further comprise as an optional additional component: One or more water-miscible organic solvents, preferably selected from the group consisting of tetrahydrofuran (THF), N-methylpyrrolidone (NMP), dimethyl formamide (DMF), dimethyl sulfoxide (DMSO), ethanol, isopropanol, butyldiglycol, butylglycol, sulfolane (2,3,4,5-tetrahydrothiophene-1,1-dioxide) and mixtures thereof; more preferably selected from the group consisting of THF, NMP, DMF, DMSO, sulfolane and mixtures thereof.

The term “water-miscible organic solvent” in the context of the present invention preferably means that an organic solvent fulfilling this requirement is miscible with water at least in a 1:1 (w/w) ratio at 20° C. and ambient pressure. Preferably the one or at least one water-miscible organic solvent (H) is sulfolane. Particularly, preferred are compositions according to the present invention which do not comprise one or more water-miscible organic solvents.

In a preferred embodiment, a composition according to the invention as defined herein is preferred wherein the total amount of the one or more water-miscible organic solvents is present in an amount of from about 0.1 to about 30% by weight, preferably of from about 0.5 to about 25% by weight, more preferably of from about 5 to about 20% by weight, even more preferably of from about 1 to about 6% by weight, based on the total weight of the composition.

In another preferred embodiment, a composition according to the invention as defined herein is preferred wherein the total amount of the one or more water-miscible organic solvents is present in an amount of from about 20 to about 55% by weight, preferably of from about 25 to about 50% by weight, more preferably of from about 30 to about 45% by weight, based on the total weight of the composition.

In yet another preferred embodiment, a composition according to the invention as defined herein comprises a first solvent selected from a mono, di- or trihydric C₁ to C₆ alkanol, preferably a di- or trihydric C₁ to C₄ alkanol, most preferably ethylene glycol or glycerol. In yet another preferred embodiment, a composition according to the invention as defined herein comprises a second solvent selected from a C₁ to C₆ alkanolamine, preferably a C₁ to C₄ alkanolamine, most preferably ethanolamine or propanolamine.

In yet another preferred embodiment, a composition according to the invention as defined herein is an aqueous solution that is essentially free of organic solvents. “Essentially free” in this context means that the content of organic solvents is below 1% by weight, preferably below 0.1% by weight, even more preferably below 0.01% by weight, most preferably below the detection limit.

### Chelating Agents

The etching composition may optionally comprise one or more chelating agents.

Preferred chelating agents are of 1,2-cyclohexylenedinitrilotetraacetic acid, 1,1,1,5,5,5-hexafluoro-2,4-pentane-dione, acetylacetonate, 2,2′-azanediyldiacetic acid, ethylenediaminetetra-acetic acid, etidronic acid, methanesulfonic acid, acetylacetone, 1,1,1-trifluoro-2,4-pentanedione, 1,4-benzoquinone, 8-hydroxyquinoline, salicyli-dene aniline; tetrachloro-1,4-benzoquinone, 2-(2-hydroxyphenyl)-benzoxazol, 2-(2-hydroxyphenyl)-benzothiazole, hydroxyquinoline sulfonic acid, sulfosali-cylic acid, salicylic acid, pyridine, 2-ethylpyridine, 2-methoxypyridine, 3-methoxypyridine, 2-picoline, dimethylpyridine, piperidine, piperazine, ethylamine, methylamine, isobutylamine, tert-butylamine, tributylamine, dipropylamine, dimethylamine, diglycol amine, methyldiethanolamine, pyrrole, isoxazole, bipyridine, py-rimidine, pyrazine, pyridazine, quinoline, isoquinoline, indole, 1-methylimidazole, diisopropylamine, diisobutylamine, aniline, pentamethyldi-ethylenetriamine, acetoacetamide, ammonium carbamate, ammonium pyr-rolidinedithiocarbamate, dimethyl malonate, methyl acetoacetate, N-methyl acetoacetamide, tetramethylammonium thiobenzoate, 2,2,6,6-tetramethyl-3,5-heptanedione, tetramethylthiuram disulfide, lactic acid, ammonium lactate, formic acid, propionic acid, gamma-butyrolactone, and mixtures thereof;

The chelating agent may be 1,2-cyclohexylenedinitrilotetraacetic acid (CDTA) or may comprise CDTA as well as one or more of the other chelating agents above.

A composition according to the invention as defined herein is also preferred wherein the amount of the one or more chelating agents present is of from about 0.01 to about 4% by weight, preferably of from about 0.02 to about 1% by weight, more preferably of from about 0.05 to about 0.8% by weight, based on the total weight of the composition.

### Surfactants

The composition may also further comprise one or more surfactants.

Preferred surfactants are selected from the group consisting of
(i) anionic surfactants, preferably selected from the group consisting of ammonium lauryl sulfate, fluorosurfactants, preferably selected from the group consisting of perfluorinated alkylsulfonamide salts (preferably perfluorinated, N-substituted alkylsulfonamide ammonium salts, PNAAS), perfluorooctanesulfonate, perfluorobutanesulfonate, perfluorononanoate and perfluorooctanoate; alkyl-aryl ether phosphates and alkyl ether phosphates;
(ii) zwitterionic surfactants, preferably selected from the group consisting of (3-[(3-cholamidopropyl)dimethylammonio]-1-propanesulfonate) (“CHAPS”), cocamidopropyl hydroxysultaine (CAS RN 68139-30-0), {[3-(dodecanoylamino)propyl](dimethyl)-ammonio}acetate, phosphatidylserine, phosphatidylethanolamine, phosphatidylcholine; and
(iii) non-ionic surfactants, preferably selected from the group consisting of glucoside alkyl ethers, glycerol alkyl ethers, cocamide ethanolamines and lauryldimethylaminoxide. More preferred surfactants in compositions according to the invention are or comprise perfluorinated, N-substituted alkylsulfonamide ammonium salts. Preferred surfactants (E) in compositions according to the invention do not comprise metals or metal ions.

A composition according to the invention as defined herein is also preferred wherein the amount of the one or more surfactants of the surfactant present is of from about 0.0001 to about 1% by weight, preferably of from about 0.0005 to about 0.5% by weight, more preferably in an amount of from about 0.001 to about 0.01% by weight, based on the total weight of the composition.

Specific surfactants for use in the compositions described herein include, but not limited to, bis(2-ethylhexyl)phosphate, perfluoroheptanoic acid, prefluorodecanoic acid, trifluoromethanesulfonic acid, phosphonoacetic acid, dodecenylsuccinic acid, dioctadecyl hydrogen phosphate, octadecyl dihydrogen phosphate, dodecylamine, dodecenylsuccinic acid monodiethanol amide, lauric acid, palmitic acid, oleic acid, juniperic acid, 12 hydroxystearic acid and dodecyl phosphate; polyoxyethylene lauryl ether (Emalmin NL-100 (Sanyo), Brij 30, Brij 98, Brij 35), dodecenylsuccinic acid monodiethanol amide (DSDA, Sanyo), ethylenediamine tetrakis(ethoxylate-block-propoxylate) tetrol (Tetronic 90R4), polyethylene glycols (e.g., PEG 400), polypropylene glycols, polyethylene or polypropylene glycol ethers, block copolymers based on ethylene oxide and propylene oxide (Newpole PE-68 (Sanyo), Pluronic L31, Pluronic 31R1, Pluronic L61, Pluronic F-127) (Dynol 607), polyoxypropylene sucrose ether (SN008S, Sanyo), t-octylphenoxypolyethoxyethanol (Triton X100), 10-ethoxy-9,9-dimethyldecan-1-amine (TRITON® CF-32), Polyoxyethylene (9) nonylphenylether, branched (IGEPAL CO-250), polyoxyethylene (40) nonylphenylether, branched (IGEPAL CO-890), polyoxyethylene sorbitol hexaoleate, polyoxyethylene sorbitol tetraoleate, polyethylene glycol sorbitan monooleate (Tween 80), sorbitan monooleate (Span 80), a combination of Tween 80 and Span 80, alcohol alkoxylates (e.g., Plurafac RA-20), alkyl-polyglucoside, ethyl perfluorobutyrate, 1,1,3,3,5,5-hexamethyl-1,5-bis[2-(5-norbornen-2-yl)ethyl]trisiloxane, monomeric octadecylsilane derivatives such as SIS6952.0 (Siliclad, Gelest), siloxane modified polysilazane such as PP1-SG10 Siliclad Glide 10 (Gelest), silicone-polyether copolymers such as Silwet L-77 (Setre Chemical Company), Silwet ECO Spreader Momentive), and ethoxylated fluorosurfactants (ZONYL® FSO-100, ZONYL® FSN-100); cetyl trimethylammonium bromide (CTAB), heptadecanefluorooctane sulfonic acid, tetraethylammonium, stearyl trimethylammonium chloride (Econol TMS-28, Sanyo), 4-(4-diethylaminophenylazo)-1-(4-nitrobenzyl)pyridium bromide, cetylpyridinium chloride monohydrate, benzalkonium chloride, benzethonium chloride, benzyldimethyldodecyl-ammonium chloride, benzyldimethylhexadecyl-ammonium chloride, hexadecyltrimethyl-ammonium bromide, dimethyldioctadecylammonium chloride, dodecyltrimethylammonium chloride, hexadecyltrimethylammonium p-toluene-sulfonate, didodecyldimethylammonium bromide, di(hydrogenated tallow) dimethylammonium chloride, tetraheptylammonium bromide, tetrakis(decyl) ammonium bromide, Aliquat® 336 and oxyphenonium bromide, guanidine hydrochloride (C(NH2)3Cl) or triflate salts such as tetrabutylammonium trifluoromethanesulfonate, dimethyldioctadecylammonium chloride, dimethyldihexadecylammonium bromide and di(hydrogenated tallow) dimethylammonium chloride (e.g., Arquad 2HT-75, Akzo Nobel). bromide-containing surfactants, such as, 1-hexadecyltrimethylammonium bromide.

In some embodiments the compositions of this invention will be free of or substantially free of any or all of the above-listed surfactants.

### Corrosion Inhibitors

The etching composition of the present invention may optionally include one or more corrosion inhibitors. The corrosion inhibitors, if present, may protect the silicon-germanium from etching. Examples of corrosion inhibitors include amino carboxylic acids, for example, triethylenetetraminehexaacetic acid (TTHA), 1,3-diamino-2-hydroxypropane-N,N,N′,N′-tetraacetic acid (DHPTA), methyliminodiacetic acid, propylenediaminetetraacetic acid, ethylenediaminetetraacetic acid (EDTA), butylenediaminetetraacetic acid, (1,2-cyclohexylenediamine)-tetraacetic acid (CyDTA), diethylenetriaminepentaacetic acid (DETPA), ethylenediaminetetrapropionic acid, (hydroxyethyl)ethylenediaminetriacetic acid (HEDTA), and nitrotriacetic acid (NTA), aminophosphonic acids, such as, N,N,N′,N′-ethylenediaminetetra(methylene-phosphonic) acid (EDTMP); carboxylic acids, such as, decanoic acid, citric acid, tartaric acid, gluconic acid, saccharic acid, glyceric acid, oxalic acid, ascorbic acid, phthalic acid, benzoic acid, mercaptobenzoic acid, maleic acid, mandelic acid, malonic acid, lactic acid and salicylic acid. Other possible corrosion inhibitors include propyl gallate, pyrogallol, quinolines, such as, 8-hydroxyquinoline, piperazines, such as, 1-(2-aminoethyl)piperazine, cysteine, and N,N,N′,N″,N″-pentamethyldiethylenetriamine (Polycat 5). Another corrosion inhibitors may include hexylamine. Some preferred corrosion inhibitors may comprise sulfur-containing groups. Other preferred corrosion inhibitors may comprise aminocarboxylic acids such as EDTA, CyDTA, quinolines, such as, 8-hydroxyquinoline, decanoic acid, 11-mercaptoundecanoic acid, piperazines, such as, 1-(2-aminoethyl)piperazine, benzimidazoles, such as, 2-mercapto-5-methylbenzimidizole, and carboxylic acids, such as, oxalic acid, decanoic acid, and ascorbic acid. More preferred corrosion inhibitors include decanoic acid, ascorbic acid, 11-mercaptoundecanoic acid, 1-(2-aminoethyl)piperazine, and 8-hydroxyquinoline. Most preferred is 8-hydroxyquinoline.

For most applications, the amount of the corrosion inhibitors, such as, amino carboxylic acids, carboxylic acids, quinolines, or piperazines, etc, in the composition may be in a range having start and end points selected from the following list of weight percents: 0.01, 0.05, 0.07, 0.1, 0.12, 0.15, 0.17, 0.2, 0.5, 1, 1.2, 1.5, 1.7, 2, 3, 4, 6, 8, 10, 12, 15. By way of example, the corrosion inhibitors may be present in the composition from about 0.05 wt % to about 3 wt %, or from about 0.01 to about 3 wt %, or about 0.1 wt % to about 5 wt %, or from about 0.1 wt % to about 15 wt %; or from about 0.1 wt % to about 10 wt %, or from about 0.5 wt. % to about 5 wt %, or from about 0.05 wt % to about 2 wt %, or about 0.5 wt % to about 5 wt % based on the total weight of the composition.

In some embodiments the compositions of this invention will be free of or substantially free of any or all of the above-listed corrosion inhibitors, that is, the composition is free of any or all of the above-listed aminocarboxylic acids and/or carboxylic acids and/or quinolines and/or piperazines, etc..

### Surface Modifiers

The composition may also comprise surface modifiers selected from halosilanes, alkoxysilanes, oligo/poly-siloxanes, e.g. methyltrimethoxysilane, 3-aminopropyl-triethoxysilane or its cyclic, linear, branched siloxanes that form in aqueous solution.

In a first embodiment the surface modifier may be selected from a siloxane compound of formulae I to IV

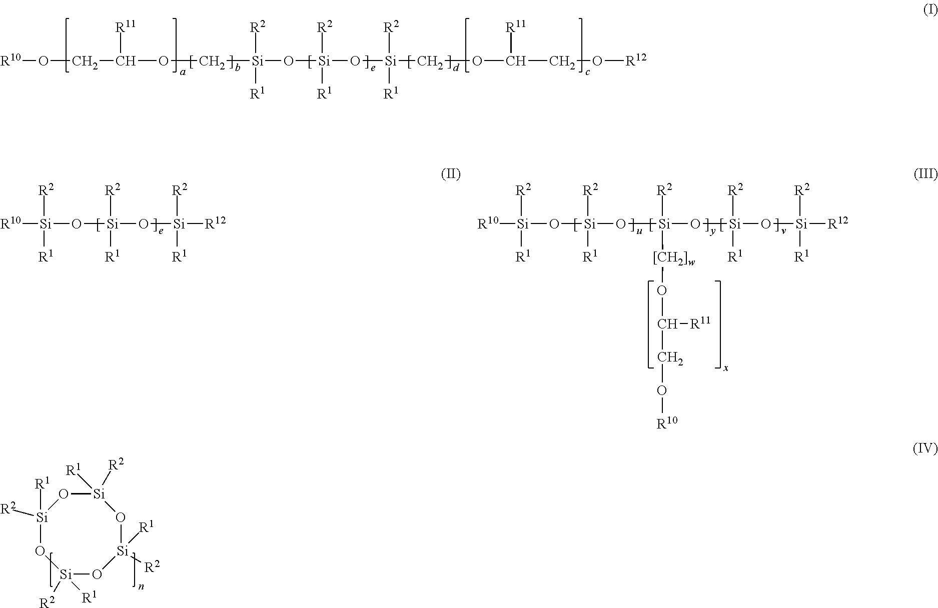

wherein
R¹, R² are independently selected from H or a C₁ to C₁₀ alkyl group,
n is 0, 1 or 2,
e, u, v are integers independently selected from 0 to 5,
b, d, w are integers independently from 0 to 6,
a, c, x are integers independently selected from 1 to 22,
y are Integers from 1 to 5,
R¹⁰, R¹² are independently is selected from H or a C₁ to C₁₀ alkyl group, and
R¹¹ is selected from H or a C₁ to C₁₀ alkyl group.

In another preferred embodiment, the siloxanes of formula I are used in, wherein
R¹, R² are independently selected from H, methyl or ethyl, preferably methyl,
e is 0, 1 or 2, preferably 1,
b, d are 0, 1 or 2, preferably 0 or 1,
a, c are integers independently selected from 0 to 10, preferably from 0 to 4,
R¹⁰, R¹² are independently selected from H, methyl or ethyl, preferably methyl, and
R¹¹ is selected from methyl or ethyl, preferably methyl.

In a preferred embodiment, the siloxanes of formula II may be used, wherein
R¹, R² are methyl,
e is 0, 1 or 2, preferably 1,
R¹⁰, R¹² are independently selected from methyl or ethyl, preferably methyl.

In yet another preferred embodiment, the siloxanes of formula III are those in which
R¹, R² are methyl or ethyl, preferably methyl,
u, v are 0 or 1, preferably 0,
w is 0 or 3, preferably 3,
x is an integer from 2 to 20, preferably from 5 to 15,
y is 1 or 2, preferably 1,
R¹⁰, R¹² are independently selected from methyl or ethyl, preferably methyl, and
R¹¹ is selected from H or methyl, preferably H.

In yet another preferred embodiment, the at least one additive may be a cyclic siloxane of formula IV, wherein
n is 1, and
R¹, R² are the same or different and selected from methyl ethyl, propyl or butyl.

The siloxane compounds of formula I to IV are available in the market e.g. under the trade names Silwet™ and Tegopren™.

Further specific embodiments of the surface modifiers as described in WO 2019/086374 may advantageously be used, which are incorporated herein by reference.

The surface modifiers may be used in a concentration range of from about 0.001 wt % to about 1.0 wt %.

### Composition

Other commonly known components such as dyes, chemical modifiers, biocides, etc. can be included in the cleaning composition in conventional amounts, for example, amounts up to a total of about 1 or 5 or 10% by weight of the composition to the extent that they do not adversely affect the performance of the composition.

Alternatively, the compositions of this invention may be free or substantially free of any or all of dyes, chemical modifiers, or biocides.

The etching solution composition of the present invention is typically prepared by mixing the components together in a vessel at room temperature until all solids have dissolved in the aqueous-based medium.

Generally, the pH of the composition may be in the range of from 8 to 14. In a preferred embodiment the pH of the etching composition is from about 9 to about 13, more preferably from about 10 to about 13, most preferably from about 11 to about 12.5. Preferably the composition is essentially free of or is free of any quaternary ammonium hydroxide and/or ammonium hydroxide.

Preferably the composition is essentially free of or is free of any polyalkyleneimine, particularly polyethyleneimine.

Preferably the composition is essentially free of or is free of a benzoquinone or a derivative of benzoquinone.

Preferably the composition is essentially free of or is free of quinoline or a derivative of Quinoline.

Preferably the composition is essentially free of or is free of an unsubstituted or substituted C₆-C₂₀ aliphatic acid.

In a preferred embodiment the composition essentially consists or consists of:
(a) 0.1 to 15% by weight of the selectivity enhancer, particularly a C₂ to C₁₀ primary alkylamine or a C₂ to C₁₀ primary alkanolamine;
(b) 0 or 0.5 to 50% by weight of an organic solvent;
(c) 0 or 0.0001 to 3% by weight, particularly 0.0001 to about 1% by weight, more particularly from 0.0005 to 0.5% by weight, even more particularly 0.001 to 0.01% by weight of a surfactant;
(d) 0 or 0.01 to 3% by weight, particularly 0.01 to 3% by weight, more particularly from 0.02 to 1% by weight, even more particularly from 0.05 to 0.8% by weight of a chelating agent;
(e) rest water.

In a preferred embodiment the composition essentially consists or consists of:
(a) 2 to 10% by weight of the selectivity enhancer, particularly tris-(2-aminoethyl)amine;
(b) 0% by weight of an organic solvent;
(c) 0 or 0.001 to 1% by weight of a surface modifier;
(d) 0 or 0.0001 to 3% by weight, particularly 0.0001 to about 1% by weight, more particularly from 0.0005 to 0.5% by weight, even more particularly 0.001 to 0.01% by weight of a surfactant;
(e) 0 or 0.01 to 3% by weight, particularly 0.01 to 3% by weight, more particularly from 0.02 to 1% by weight, even more particularly from 0.05 to 0.8% by weight of a chelating agent;
(f) rest water.

In a preferred embodiment the composition essentially consists or consists of:
(a) 2 to 10% by weight of an amine of formula E1, particularly tris-(2-aminoethyl)amine;
(b) 2 to 25% by weight of one or more organic solvents, particularly ethylene glycol, propylene glycol, glycerol, or combinations thereof;
(c) 0 or 0.001 to 1% by weight of a surface modifier;
(d) 0 or 0.0001 to 3% by weight, particularly 0.0001 to about 1% by weight, more particularly from 0.0005 to 0.5% by weight, even more particularly 0.001 to 0.01% by weight of a surfactant;
(e) 0 or 0.01 to 3% by weight, particularly 0.01 to 3% by weight, more particularly from 0.02 to 1% by weight, even more particularly from 0.05 to 0.8% by weight of a chelating agent;
(f) rest water.

In a preferred embodiment the composition essentially consists or consists of:
(a) 2 to 10% by weight of an amine of formula E1, particularly tris-(2-aminoethyl)amine;
(b) 5 to 25% by weight of a C₂ to Ce polyol, particularly glycerol;
(c) 0 or 0.001 to 1% by eight of a surface modifier;
(d) 0 or 0.0001 to 3% by weight, particularly 0.0001 to about 1% by weight, more particularly from 0.0005 to 0.5% by weight, even more particularly 0.001 to 0.01% by weight of a surfactant;
(e) 0 or 0.01 to 3% by weight, particularly 0.01 to 3% by weight, more particularly from 0.02 to 1% by weight, even more particularly from 0.05 to 0.8% by weight of a chelating agent;
(f) rest water.

In a preferred embodiment the composition essentially consists or consists of the selectivity enhancer and water.

In a particularly preferred embodiment the composition essentially consists or consists of 1 to 12, preferably 2 to 10, most preferably 3 to 7% by weight of the selectivity enhancer, particularly a primary alkylamine, most particularly tris-(2-aminoethyl)amine, and water.

In another particularly preferred embodiment the composition essentially consists of the selectivity enhancer, one or more of the organic solvents, and water.

“Essentially” in this context means that the content of any other compounds except the specifically mentioned ones are below 1% by weight, preferably below 0.1% by weight, even more preferably below 0.01% by weight, most preferably below the detection limit.

A composition according to the invention as defined herein is specifically preferred wherein the composition consists of the amine of formula E1 and water as defined herein and to be defined based on the examples.

### Application

In another aspect there is provided a process of selectively removing a silicon layer from a surface of a microelectronic device relative to an n-doped silicon layer, the process comprising:
(a) providing a microelectronic device surface that includes the silicon layer and the n-doped silicon layer, wherein the n-doped silicon layer has a content of 10¹⁶ cm⁻³ to 10²² cm⁻³ of a group 13 or 15 element;
(b) providing an etching composition comprising
   (i) 0.1 to 15% by weight of a selectivity enhancer selected from a C₁ to C₂₀ primary alkylamine, a C₁ to C₂₀ secondary alkylamine, a C₁ to C₂₀ primary alkanolamine, and a C₁ to C₂₀ secondary alkanolamine; and
   (ii) water;
(c) contacting the surface with the composition at a temperature of 10 to 50° C. for a time and at a temperature effective to selectively remove the silicon layer relative to the n-doped silicon layer.

In yet another aspect there is provided a method of for selectively enhancing the etch rate of silicon relative to n-doped silicon in a microelectronic device e.g. composite semiconductor device comprising silicon and n-doped silicon by etching the microelectronic device (composite semiconductor device) by using a composition as described herein.

It will be appreciated that it is common practice to make concentrated forms of the compositions to be diluted prior to use. For example, the compositions may be manufactured in a more concentrated form and thereafter diluted with water, at least one oxidizing agent, or other components at the manufacturer, before use, and/or during use. Dilution ratios may be in a range from about 0.1 parts diluent to 1 parts composition concentrate to about 100 parts diluent to 1 part composition concentrate.

In the use of the compositions described herein, the composition typically is contacted with the device structure for a sufficient time of from about 1 minute to about 200 minutes, preferably about 5 minutes to about 60 minutes, at temperature in a range of from about 50° C. to about 90° C., preferably about 60° C. to about 80° C. Such contacting times and temperatures are illustrative, and any other suitable time and temperature conditions may be employed that are efficacious to achieve the required removal selectivity.

It was found that the silicon/dope silicon etch ratio is particularly advantageous at low temperatures below 50° C., preferably below 45° C., even more preferably below 40° C., even more preferably below 34° C., even more preferably below 30° C. Etching at temperature below 10° C. may generally be possibly but is economically disadvantageous.

Following the achievement of the desired etching action, the composition can be readily removed from the microelectronic device to which it has previously been applied, e.g., by rinse, wash, or other removal step(s), as may be desired and efficacious in a given end use application of the compositions of the present invention. For example, the device may be rinsed with a rinse solution including deionized water, an organic solvent, and/or dried (e.g., spin-dry, N₂, vapor-dry etc.).

It may be useful to clean the blanket wafer surfaces (removal of oxide) for about 10 s to about 120 s with an aqueous solution containing about 0.1% to 5% by weight HF at room temperature.

Preferably the silicon etch rates of the compositions according to the invention are 2000 A/min or more, more preferably 3000 A/min or more. Preferably the n-doped silicon, particularly the Si:P etch rates of the compositions according to the invention are 30 A/min or below, more preferably 25 A/min or below. Preferably the etch rate of the layer comprising silicon is at least 30, preferably 50, even more preferably 80, even more preferably preferably 120, most preferably more than 150 times faster than the etch rate of the n-doped silicon layer (silicon/dope silicon selectivity).

After the contacting step is an optional rinsing step. The rinsing step may be carried out by any suitable means, for example, rinsing the substrate with de-ionized water by immersion or spray techniques. In preferred embodiments, the rinsing step may be carried out employing a mixture of de-ionized water and an organic solvent such as, for example, isopropanol.

After the contacting step and the optional rinsing step is an optional drying step that is carried out by any suitable means, for example, isopropanol (IPA) vapor drying, heat, or by centripetal force.

The etching composition described herein may be advantageously used in a process for the manufacture of a semiconductor device, comprising the step of selectively removing silicon from a surface of a microelectronic device relative to a phosphorous doped silicon containing material described herein.

All percent, ppm or comparable values refer to the weight with respect to the total weight of the respective composition except where otherwise indicated. The terms “% by weight” and “wt %” are used herein synonymously. All cited documents are incorporated herein by reference.

The following examples shall further illustrate the present invention without restricting the scope of this invention.

### EXAMPLES

### General Procedures and Substrates

The following substrates were used: PolySilicon containing blanket wafers (500 nm PolySi on 100 nm SiO₂) and phosphorous doped polysilicon blanket wafers (300 nm PolySi on 100 nm SiO₂ having 0.5 or 4.0 mΩ cm).

All amounts given for the compounds in the compositions are absolute amounts, i.e. excluding water, in the overall mixture.

### Etch Bath Preparation:

The etchant was prepared by adding the respective additive to DI water. The etchant was transferred into a plastic beaker equipped with a thermostat.

### Pre-Etching:

UPW and 1 wt % hydrogen fluoride were filled into two plastic beakers. Each coupon (Si:P, poly-Si) was pre-etched in 1 wt % hydrogen fluoride for 30 s, then dipped into UPW for 2-3 s and dried with compressed air.

Wafer coupons of about 2.5 cm×2.5 cm of poly-silicon (Poly-Si) and phosphorous doped silicon (Si:P) with a phosphorous content of 7·10¹⁹ cm⁻³ were prepared and rinsed with iso-propanol and dried with a nitrogen stream. Right before etching, the coupons are submerged into 1% aqueous HF in a plastic vessel for 1 minute, rinsed with DI water and added to the etchant as described below.

The etchant was set to the specified temperature +/−0.5° C. Once the temperature was reached, the poly-Si or Si:P wafer coupons were submerged into the etchant. Each coupon was etched separately for 0.5 to 2 minutes, depending on substrate thickness, under stirring, subsequently rinsed with DI water and dried. All experiments were conducted under argon atmosphere.

The resulting thickness was determined by spectroscopic ellipsometry.

### Example 1

The compositions listed in table 1 were prepared. The etching rates were determined by ellipsometry by comparing the layer thickness before and after etching. The results are also depicted in table 1.

TABLE 1

| | | | | E.r. | E.r. | |
|---|---|---|---|---|---|---|
| Exam- | | T | | Si | Si:P | E.r. |
| ple | Etchant | [° C.] | pH | [Å/min] | [Å/min] | Si/Si:P |
| C1 | 5% TMAH | 55 | 13.6 | 2864 | 2213 | 1.3 |
| C2 | 5% DBU | 55 | 13.4 | 734 | 199 | 3.7 |
| C3 | 5% Ethanolamine | 55 | 11.7 | 3258 | 1243 | 2.6 |
| C4 | 5% Diethanolamine | 55 | 11.2 | 1351 | 691 | 2.0 |
| C5 | 5% Triethanolamine | 55 | 10.6 | 94 | 19 | 4.9 |
| C7 | 5% Tren | 55 | 11.8 | 3524 | 809 | 4.4 |
| C8 | 5% TMAH | 30 | 13.6 | 53 | 6 | 8.8 |
| C9 | 5% DBU | 30 | 13.4 | 32 | 6 | 5.3 |
| 10 | 5% Ethanolamine | 30 | 11.7 | 592 | 7 | 85 |
| 11 | 5% Diethanolamine | 30 | 11.2 | 229 | 6 | 38 |
| C12 | 5% Triethanolamine | 30 | 10.6 | 8 | 3 | 2.7 |
| 13 | 5% Tren | 30 | 11.7 | 1156 | 7 | 174 |

TMAH = tetramethylammonium hydroxide
DBU = 1,8-diazabicyclo[5.4.0]undec-7-en
TREN = tris(2-aminoethyl) amine

Table 1 shows that all amine etchants as well as strong bases like TMAH or DBU showed a low or moderate selectivity for poly-Si over poly-Si:P at 55° C.

Compared to 55° C., the primary and secondary amine etchants ethanolamine, diethanolamine, and TREN performed much better at 30° C. with selectivities increasing by a factor of 10, whereas selectivity of DBU stays roughly the same and that of triethanolamine (tertiary amine) and TMAH dropped even further. The selectivity increases from secondary to primary alkyamines and alkanolamines. Highest selectivity was observed with an aqueous solution of TREN.

1. A method of using a composition, the method comprising using the composition for selectively etching a silicon layer in the presence of an n-doped silicon layer at a temperature from 10 to 50° C., the composition comprising:
(a) 0.1 to 15% by weight of a selectivity enhancer selected from the group consisting of a C₁ to C₂₀ primary alkylamine, a C₁ to C₂₀ secondary alkylamine, a C₁ to C₂₀ primary alkanolamine, and a C₁ to C₂₀ secondary alkanolamine; and
(b) water;
wherein the n-doped silicon has a content of from 10¹⁶ cm⁻³ to 10²² cm⁻³ of a group 13 or 15 element.

2. The method according to claim 1, wherein the selectivity enhancer is a C₁ to C₁₀ primary amine or a C₁ to C₁₀ primary alkanolamine.

3. The method according to claim 1, wherein the selectivity enhancer is a compound of formula E1 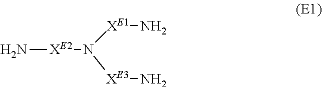
wherein
X^{E1}, X^{E1}, X^{E1} are independently selected from the group consisting of a C₂-C₆ alkanediyl;

4. The method according to claim 3, wherein X^{E1} is selected from the group consisting of methanediyl, ethane-1,2-diyl, propane-1,3-diyl, and propane-1,2-diyl.

5. The method according to claim 1, wherein the selectivity enhancer is a compound of formula E2a or E2b 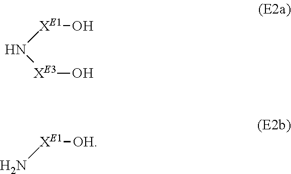
wherein
X^{E1}, X^{E1}, X^{E1} are independently selected from the group consisting of a C₂-C₆ alkanediyl.

6. The method according to claim 1, wherein the selectivity enhancer is selected from the group consisting of ethanolamine, propanolamine, tris-(2-aminoethyl)amine (TREN), tris-(3-aminopropyl)amine, and 1-(2-Aminoethyl)piperazine.

7. The method according to claim 1, further comprising an organic solvent miscible with water.

8. The method according to claim 1, wherein the composition consists essentially of:
(a) 0.1 to 15% by weight of the primary or secondary amine or primary or secondary alkanolamine;
(b) 0 to 50% by weight of an organic solvent;
(c) 0 to 3% by weight of a surfactant;
(d) 0 to 3% by weight of a chelating agent; and
(e) rest water.

9. The method according to claim 1, wherein the composition consists essentially of the selectivity enhancer and water.

10. The method according to claim 1, wherein the composition has a pH of 10 to 13.

11. The method according to claim 1, wherein selectively etching a silicon layer in the presence of an n-doped silicon layer is at a temperature from 20 to 40° C.

12. A process of selectively removing a silicon layer from a surface of a microelectronic device relative to an n-doped silicon layer, the process comprising:
(a) providing a microelectronic device surface that includes the silicon layer and the n-doped silicon layer, wherein the n-doped silicon layer has a content of 10¹⁶ cm⁻³ to 10²² cm⁻³ of a group 13 or 15 element;
(b) providing an etching composition comprising
(i) 0.1 to 15% by weight of a selectivity enhancer selected from the group consisting of a C₁ to C₂₀ primary alkylamine, a C₁ to C₂₀ secondary alkylamine, a C₁ to C₂₀ primary alkanolamine, and a C₁ to C₂₀ secondary alkanolamine; and
(ii) water; and
(c) contacting the surface with the composition at a temperature of 10 to 50° C. for a time and at a temperature effective to selectively remove the silicon layer relative to the n-doped silicon layer.

13. The process according to claim 12, wherein step (c) is performed at a temperature of 20 to 40° C.

14. A process for the manufacture of a semiconductor device, comprising the step of selectively removing silicon from a surface of a microelectronic device relative to a phosporous doped silicon containing material according to claim 12.

15. The method according to claim 1, wherein the n-doped silicon has a content of from 10¹⁷ cm⁻³ to 10²¹ cm⁻³ of a group 13 or 15 element.

16. The method according to claim 1, wherein the n-doped silicon has a content of from 10¹⁸ cm⁻³ to 10²⁰ cm⁻³ of a group 13 or 15 element.

17. The method according to claim 1, wherein the composition has a pH of 11 to 12.5.
